(19) United States
(12) Patent Application Publication
(10) Pub. No.: US 2022/0359494 A1
(43) Pub. Date: Nov. 10, 2022

(54) Latch-up Free Lateral IGBT Device

(71) Applicant: NuVolta Technologies (Hefei) Co., Ltd., Hefei (CN)

(72) Inventors: John Lin, Carlsbad, CA (US); Jinbiao Huang, Nashua, NH (US)

(21) Appl. No.: 17/657,990

(22) Filed: Apr. 5, 2022

Related U.S. Application Data
(60) Provisional application No. 63/185,448, filed on May 7, 2021.

(51) Int. Cl. H01L 27/02; H01L 29/10; H01L 29/06; H01L 21/8232; H01L 29/66; H01L 29/739; H01L 27/06

(52) U.S. Cl. CPC H01L 27/0248; H01L 29/1095; H01L 29/0696; H01L 21/8232; H01L 29/66325; H01L 29/7393; H01L 29/1033; H01L 27/0617; H01L 21/8249

(57) ABSTRACT

An apparatus includes a drift region formed over the substrate, a body region over the substrate, a first well region formed over the drift region, a collector region formed in the first well region, an emitter region formed in the body region, a first body contact formed in the body region, a first gate situated between the collector region and the emitter region, a second well region formed over the substrate, a drain region formed in the second well region, wherein the drain region and the emitter region are electrically connected to each other, a source region formed in the second well region, wherein the source region and the first body contact are electrically connected to each other, and a second gate situated between the drain region and the source region, wherein the second gate and the first gate are electrically connected to each other.

### PRIORITY

This application claims the benefit of U.S. Provisional Application No. 63/185,448, filed on May 7, 2021, entitled “Latch-up Free Lateral IGBT Device,” which application is hereby incorporated herein by reference.

### TECHNICAL FIELD

The present invention relates to a lateral Insulated Gate Bipolar Transistors (IGBT) device, and, in particular embodiments, to a latch-up free lateral IGBT device.

### BACKGROUND

As semiconductor technologies evolve, the IGBT device has been widely used in high current applications. The IGBT device is a switching device with high input impedance and large bipolar current carrying capability. The IGBT device combines the characteristics of metal oxide semiconductor field effect transistors (MOSFETs) and bipolar junction transistors (BJTs) to attain high input impedance and low saturation voltage capacity respectively. The MOSFET portion of the IGBT device provides the high input impedance. The BJT portion of the IGBT device provides large bipolar current carrying capability. The IGBT device is capable of handling large collector-emitter currents with a low gate drive loss.

The IGBT device can be constructed with a simplified equivalent circuit having a MOSFET, a PNP transistor and an NPN transistor. The collector of the PNP transistor is connected to the base of the NPN transistor. The collector of the NPN transistor is connected to the base of the PNP transistor. The drain of the MOSFET is coupled to the collector of the NPN transistor. The source of the MOSFET is connected to the emitter of the NPN transistor. An IGBT device has three terminals, namely Collector (C), Emitter (E) and Gate (G). The collector terminal of the IGBT device is connected to the emitter of the PNP transistor. The gate terminal of the IGBT device is connected to the gate of the MOSFET. The emitter terminal of the IGBT device is connected to the emitter of the NPN transistor. A resistor representing the body region resistance is connected between the base and emitter of the NPN transistor. A resistor representing the drift region resistance is connected between the drain of the MOSFET and the collector of the NPN transistor.

In operation, the gate terminal is used to control the on/off of the IGBT device. When a control voltage is applied to the gate terminal, and the control voltage is greater than the turn-on threshold of the IGBT device, a current path is established between the collector terminal and the emitter terminal of the IGBT device. On the other hand, when the control voltage applied to the gate terminal is less than the threshold of the IGBT device, the IGBT device is turned off accordingly.

The NPN transistor of the IGBT device is a parasitic transistor. The NPN transistor and the PNP transistor of the IGBT device can form a thyristor. If the NPN transistor is inadvertently turned on, latch-up can occur. Once the IGBT device is in latch-up, the gate terminal no longer has any control of the current flowing through the IGBT device and the IGBT device cannot be turned off by the gate terminal. After latch-up occurs, the IGBT device may be damaged by the excessive power dissipation. Latch-up is a highly undesirable operating condition. It is desirable to have a simple and reliable circuit to avoid latch-up.

### SUMMARY

These and other problems are generally solved or circumvented, and technical advantages are generally achieved, by preferred embodiments of the present disclosure which provide a latch-up free lateral IGBT device.

In accordance with an embodiment, an apparatus comprises a substrate of a first conductivity, a drift region of a second conductivity formed over the substrate, a body region of the first conductivity formed over the substrate, a first well region of the second conductivity formed over the drift region, a collector region of the first conductivity formed in the first well region, an emitter region of the second conductivity formed in the body region, a first body contact of the first conductivity formed in the body region, a first gate situated between the collector region and the emitter region, a second well region of the first conductivity formed over the substrate, a drain region of the second conductivity formed in the second well region, wherein the drain region and the emitter region are electrically connected to each other, a source region of the second conductivity formed in the second well region, wherein the source region and the first body contact are electrically connected to each other, and a second gate situated between the drain region and the source region, wherein the second gate and the first gate are electrically connected to each other.

In accordance with another embodiment, a method comprises forming a drift region having a second conductivity over a substrate with a first conductivity, forming a body region with the first conductivity type in the drift region, forming a first well region of the second conductivity, a body region of the first conductivity and a second well region of the first conductivity over the drift region, forming a collector region of the first conductivity in the well region, an emitter region of the second conductivity in the body region, a drain region of the second conductivity and a source region of the second conductivity in the second well region, wherein the drain region and the emitter region are electrically connected to each other, forming a first gate between the collector region and the emitter region, and forming a second gate between the drain region and the source region, wherein the second gate and the first gate are electrically connected to each other.

In accordance with yet another embodiment, a device comprises a first collector region, a gate region and a second collector region formed over a drift layer, wherein the gate region is oriented from the first collector region to the second collector region, a plurality of emitter/drain regions and a plurality of source/body regions formed in an alternating manner over the drift layer, wherein the first collector region and an emitter region of the plurality of emitter/drain regions form an upper IGBT cell, the second collector region and the emitter region of the plurality of emitter/drain regions form a lower IGBT cell, and a drain region of the plurality of emitter/drain regions and a source region of the plurality of source/body regions form an NMOS transistor, and wherein the drain region and the emitter region are electrically connected to each other.

The foregoing has outlined rather broadly the features and technical advantages of the present disclosure in order that the detailed description of the disclosure that follows may be better understood. Additional features and advantages of the disclosure will be described hereinafter which form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 illustrates a simplified cross-sectional view of a latch-up free IGBT device in accordance with various embodiments of the present disclosure;

FIG. 2 illustrates an equivalent circuit diagram of the latch-up free IGBT device illustrated in FIG. 1 in accordance with various embodiments of the present disclosure;

FIG. 3 illustrates a simplified top view of a first implementation of the layout of the latch-up free IGBT device shown in FIG. 1 in accordance with various embodiments of the present disclosure;

FIG. 4 illustrates a simplified top view of a second implementation of the layout of the latch-up free IGBT device shown in FIG. 1 in accordance with various embodiments of the present disclosure; and

FIG. 5 illustrates a flow chart of a method for forming the latch-up free IGBT device shown in FIG. 1 in accordance with various embodiments of the present disclosure.

Corresponding numerals and symbols in the different figures generally refer to corresponding parts unless otherwise indicated. The figures are drawn to clearly illustrate the relevant aspects of the various embodiments and are not necessarily drawn to scale.

### DETAILED DESCRIPTION OF ILLUSTRATIVE EMBODIMENTS

The making and using of the presently preferred embodiments are discussed in detail below. It should be appreciated, however, that the present disclosure provides many applicable inventive concepts that can be embodied in a wide variety of specific contexts. The specific embodiments discussed are merely illustrative of specific ways to make and use the disclosure, and do not limit the scope of the disclosure.

The present disclosure will be described with respect to embodiments in a specific context, a latch-up free lateral IGBT device. The embodiments of the disclosure may also be applied, however, to a variety of IGBT devices (e.g., vertical IGBT devices). Hereinafter, various embodiments will be explained in detail with reference to the accompanying drawings.

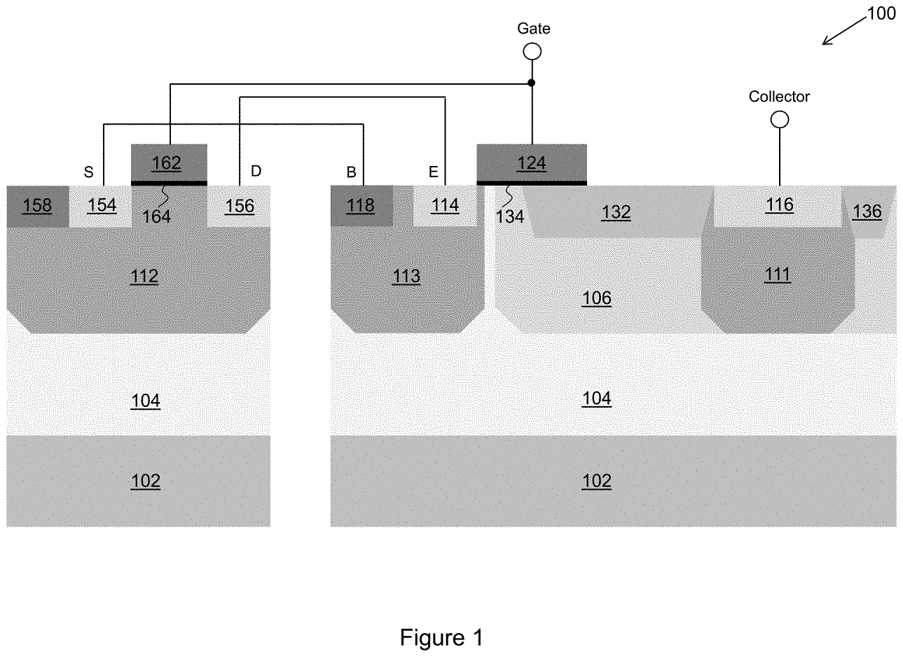

FIG. 1 illustrates a simplified cross-sectional view of a latch-up free IGBT device in accordance with various embodiments of the present disclosure. The latch-up free IGBT device 100 include a substrate 102, a first layer 104, a drift layer 106 formed over the first layer 104, a body region 113, a first well 111 and a second well 112. The latch-up free IGBT device 100 further comprises a collector region 116 formed in the first well 111, an emitter region formed in the body region 113, a first body contact 118 formed in the body region 113, a first gate dielectric layer 134, a first gate 124, a first shallow trench isolation (STI) region 132 and a second STI region 136. The latch-up free IGBT device 100 further comprises a drain region 156 formed in the second well 112, a source region 154 formed in the second well 112, a second body contact 158 formed in the second well 112, a second gate dielectric layer 164 and a second gate 162.

In some embodiments, the substrate 102, the body region 113, the first body contact 118, the collector region 116, the second well 112 and the second body contact 158 have a first conductivity type. The drift layer 106, the first well 111, the emitter region 114, the drain region 156 and the source region 154 have a second conductivity type. In some embodiments, the first conductivity type is p-type, and the second conductivity type is n-type. The latch-up free IGBT device 100 is an n-channel IGBT device. Alternatively, the first conductivity type is n-type, and the second conductivity type is p-type. The latch-up free IGBT device 100 is a p-channel IGBT device.

The substrate 102 may be formed of suitable semiconductor materials such as silicon, silicon germanium, silicon carbide and the like. Depending on different applications and design needs, the substrate 102 may be n-type or p-type. In some embodiments, the substrate 102 is a p-type substrate. Appropriate p-type dopants such as boron and the like are doped into the substrate 102. Alternatively, the substrate 102 is an n-type substrate. Appropriate n-type dopants such as phosphorous and the like are doped into the substrate 102.

In some embodiments, the first layer 104 may be a p-type epitaxial layer. The p-type epitaxial layer is grown over the substrate 102. The epitaxial growth of the epitaxial layer may be implemented by using any suitable semiconductor fabrication processes such as chemical vapor deposition (CVD) and the like. In alternative embodiments, the first layer 104 may comprise an epitaxial layer and a buried layer. In some embodiments, both the epitaxial layer and the buried layer are n-type layers. The n-type buried layer is formed between the substrate 102 and the n-type epitaxial layer. The n-type buried layer is deposited over the substrate 102 for isolation purposes. For example, the n-type buried layer is employed to prevent the current from flowing into the substrate 102, thereby avoiding the leakage in the latch-up free IGBT device 100. The n-type epitaxial layer is grown over the substrate 102. The epitaxial growth of the epitaxial layer may be implemented by using any suitable semiconductor fabrication processes such as CVD and the like. In some embodiments, the n-type epitaxial layer is of a doping density in a range from about 10¹⁴/cm³ to about 10¹⁶/cm³.

The drift layer 106 is an n-type layer formed over the first layer 104. In some embodiments, the drift layer 106 may be doped with an n-type dopant such as phosphorous to a doping density of about 10¹⁵/cm³ to about 10¹⁷/cm³. It should be noted that other n-type dopants such as arsenic, antimony, or the like, could alternatively be used.

The body region 113 is a p-type body region. The p-type body region 113 may be formed by implanting p-type doping materials such as boron and the like. Alternatively, the p-type body region 113 can be formed by a diffusion process. In some embodiments, a p-type material such as boron may be implanted to a doping density of about 10¹⁶/cm³ to about 10¹⁸/cm³. It should be noted that there is a gap between the body region 113 and the drift layer 106 as shown in FIG. 1. The first layer 104 occupies the gap between the body region 113 and the drift layer 106.

The first well 111 is an n-type region. The first well 111 may be formed by implanting n-type doping materials such as phosphor and the like. Alternatively, the first well 111 can be formed by a diffusion process. In some embodiments, an n-type material such as phosphor may be implanted to a doping density of about 10¹⁶/cm³ to about 10¹⁸/cm³.

The second well 112 is a p-type region. The second well 112 may be formed by implanting p-type doping materials such as boron and the like. Alternatively, the second well 112 can be formed by a diffusion process. In some embodiments, a p-type material such as boron may be implanted to a doping density of about 10¹⁶/cm³ to about 10¹⁸/cm³.

The collector region 116 is a P+ region formed in the first well 111. The collector region 116 may be formed by implanting a p-type dopant such as boron at a concentration of between about 10¹⁹/cm³ and about 10²⁰/cm³.

As shown in FIG. 1, the collector region 116 is formed between the first STI region 132 and the second STI region 136. The STI regions (e.g., first STI region 132) may be formed by etching the semiconductor device to form a trench and filling the trench with a dielectric material. In accordance with an embodiment, the isolation regions may be filled with a dielectric material such as an oxide material and the like. The STI regions are employed to improve the breakdown voltage of the latch-up free IGBT device 100. It should be noted that while FIG. 1 shows the STI regions 132 and 136 may be separate isolation regions, the STI regions 132 and 136 may be portions of a continuous isolation region.

The emitter region 114 is an N+ region formed in the body region 113. The emitter region 114 may be formed by implanting an n-type dopant such as phosphorous and arsenic at a concentration of between about 10¹⁹/cm³ and about 10²⁰/cm³.

The first body contact 118 is a P+ region formed in the body region 113. The first body contact 118 may be formed by implanting a p-type dopant such as boron at a concentration of between about 10¹⁹/cm³ and about 10²⁰/cm³. In operation, the holes are injected from the collector region 116 to the first body contact 118 through two paths. A first path is formed by the collector region 116, the first well 111, the drift layer 106, the body region 113 and the first body contact 118. A second path is formed by the collector region 116, the first well 111, the first layer 104, the body region 113 and the first body contact 118.

The drain region 156 is an N+ region formed in the second well 112. The drain region 156 may be formed by implanting n-type dopants such as phosphorous and arsenic at a concentration of between about 10¹⁹/cm³ and about 10²⁰/cm³.

The source region 154 is an N+ region formed in the second well 112. The source region 154 may be formed by implanting n-type dopants such as phosphorous and arsenic at a concentration of between about 10¹⁹/cm³ and about 10²⁰/cm³.

The second body contact 158 is a P+ region formed in the second well 112. As shown in FIG. 1, the second body contact 158 is formed immediately adjacent to the source region 154. The second body contact 158 may be formed by implanting a p-type dopant such as boron at a concentration of between about 10¹⁹/cm³ and about 10²⁰/cm³. The second body contact 158 may contact the p-type body (e.g., the second well 112). In order to eliminate the body effect, the second body contact 158 may be connected to the source region 154 directly through a source contact (not shown).

The first gate dielectric layer 134 and the second gate dielectric layer 164 may be two portions of a same dielectric layer. As shown in FIG. 1, the first gate dielectric layer 134 is formed over the drift layer 106. The first gate dielectric layer 134 is partially on top of the body region 113, partially on top of the drift layer 106 and partially on top of the first STI region 132. The second gate dielectric layer 164 is formed over the second well 112. The second gate dielectric layer 164 is formed between the source region 154 and the drain region 156.

The first gate 124 is formed on the first gate dielectric layer 134. The second gate 162 is formed on the second gate dielectric layer 164. The first gate 124 and the second gate 162 may be two portions of a same gate layer formed of polysilicon, polysilicon germanium, nickel silicide or other metal, metal alloy materials.

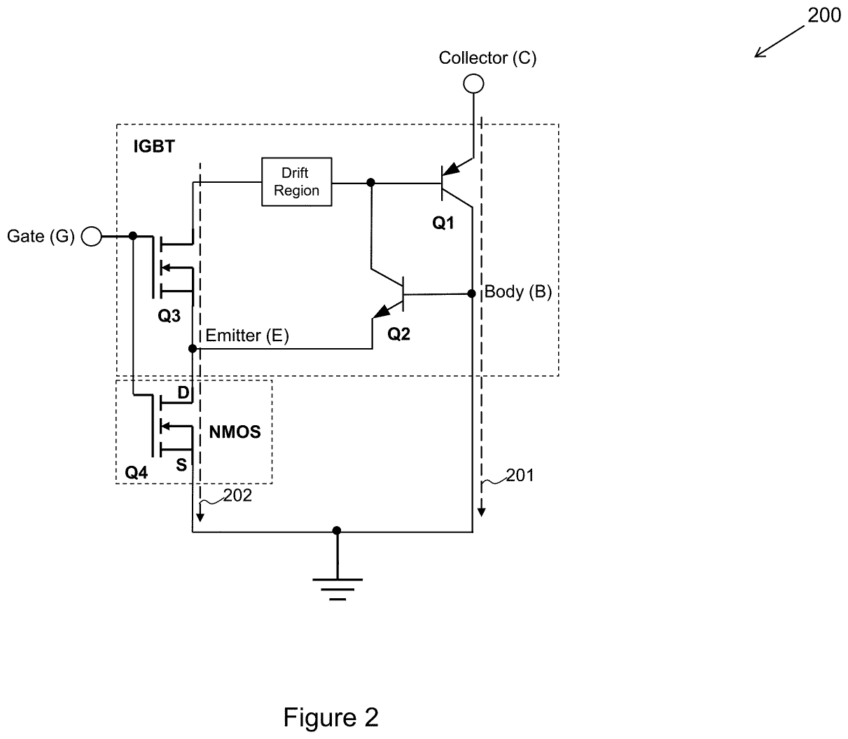

In some embodiments, the collector region 116, the emitter region 114, the first body contact 118 and the first gate 124 form a lateral IGBT device. The drain region 156, the source region 154 and the second gate 162 form a MOSFET device. As shown in FIG. 1, the drain region 156 and the emitter region 114 are electrically connected to each other. The source region 154 and the first body contact 118 are electrically connected to each other. The second gate 162 and the first gate 124 are electrically connected to each other. The configuration of the lateral IGBT device and the MOSFET device shown in FIG. 1 helps to prevent the lateral IGBT device from entering a latch-up operating condition. In some embodiments, a channel width ratio of the MOSFET device to the lateral IGBT device is selected to prevent the lateral IGBT device from entering a latch-up operating condition. The detailed operating principle of the lateral IGBT device and the MOSFET device will be described in detail with respect to FIG. 2.

It should be noted that although the implementation shown in FIG. 1 depicts the latch-up free IGBT device 100 having a p-type collector region 116, an n-type well 111, an n-type drift layer 106, a p-type body region 113, a p-type type body contact 118 and an n-type emitter region 114. This conductivity arrangement is configured to produce an n-type conduction channel. It should be noted that this conductivity arrangement is merely an example. In other implementations, the described polarities can be reversed such that the latch-up free IGBT device 100 may have a p-type conduction channel.

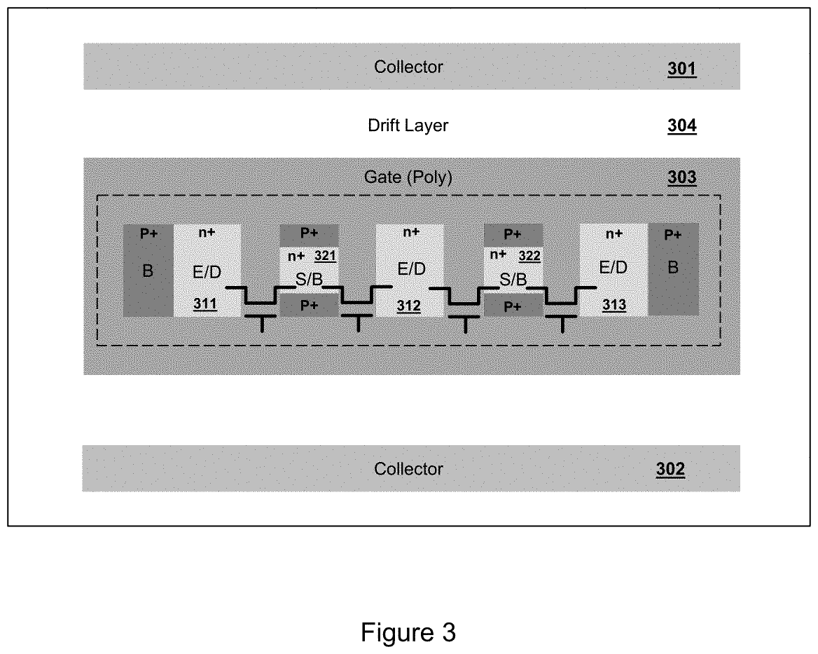

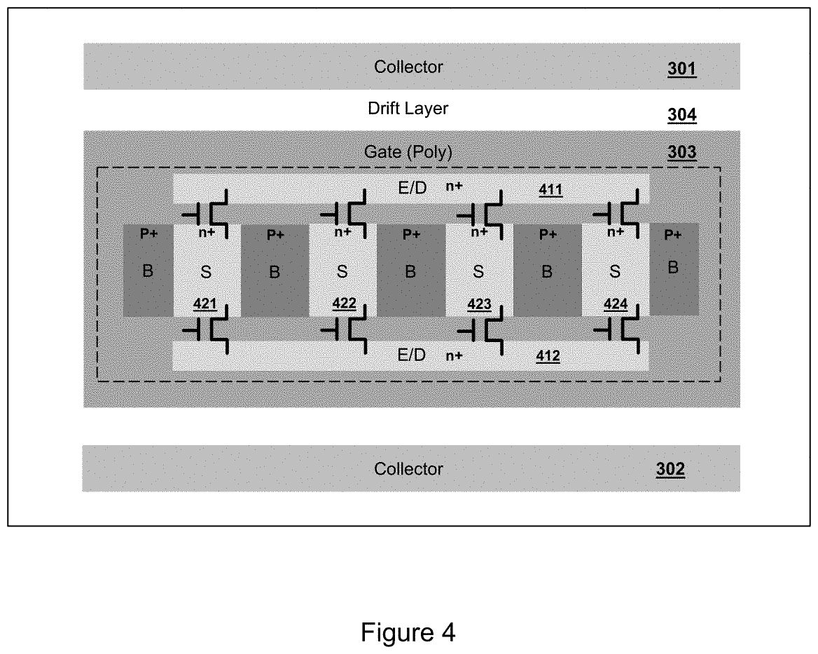

It should further be noted that to aid understanding and clarity, the MOSFET and the IGBT shown in FIG. 1 are not merged into one single device so that the electrical connections can be better illustrated. In a real layout of the latch-up free IGBT device, the MOSFET and the IGBT are merged into one single device as shown in FIGS. 3-4 below.

FIG. 2 illustrates an equivalent circuit diagram of the latch-up free IGBT device illustrated in FIG. 1 in accordance with various embodiments of the present disclosure. An equivalent circuit 200 of the latch-up free IGBT device 100 illustrated in FIG. 1 includes a bipolar PNP transistor Q1, a bipolar NPN transistor Q2, a first NMOS transistor Q3 and a second NMOS transistor Q4. The bipolar NPN transistor Q2 is a parasitic transistor. The second NMOS transistor Q4 is employed to prevent the lateral IGBT device from entering a latch-up operating condition. Referring back to FIG. 1, the second NMOS transistor Q4 is formed by the drain region 156, the source region 154 and the second gate 162.

As shown in FIG. 2, the base of the bipolar PNP transistor Q1 is connected to the collector of the bipolar NPN transistor Q2. The base of the bipolar NPN transistor Q2 is connected to the collector of the bipolar PNP transistor Q1. The drain of the first NMOS transistor Q3 is connected to the collector of the bipolar NPN transistor through a drift region. The source of the first NMOS transistor Q3 is connected to the drain of the second NMOS transistor Q4, and further connected to the emitter of the bipolar NPN transistor Q2. The gate of the first NMOS transistor Q3 is connected to the gate of the second NMOS transistor Q4.

The IGBT device shown in FIG. 2 has four terminals C, B, E and G. The collector (C) of the IGBT device is the emitter of the bipolar PNP transistor Q1. The emitter (E) of the IGBT device is the emitter of the bipolar NPN transistor Q2. The body (B) of the IGBT device is connected to the base of the bipolar NPN transistor Q2. The gate (G) of the IGBT device is connected to the gate of the first NMOS transistor Q3.

As shown in FIG. 2, while the base of the bipolar NPN transistor Q2 is connected to ground, there may be a resistor (not shown) coupled between the base of the bipolar NPN transistor Q2 and ground. The resistor represents the body resistance of the body region 113 shown in FIG. 1. It should be noted that the resistance between the base of the bipolar NPN transistor Q2 and ground may have an impact on whether the IGBT device enters into the latch-up mode. As shown in FIG. 2, the collector current of the IGBT device comprises two components. A first component is indicated by the dashed line 201. A second component is indicated by the dashed line 202. In operation, when the voltage (the product of the first component of the collector current and the resistance of the body region) is greater than the turn-on threshold of the bipolar NPN transistor Q2, the parasitic NPN transistor is inadvertently turned on. As a result of turning on the parasitic NPN transistor, latch-up can occur. As described below, the second NMOS transistor Q4 can prevent the IGBT device from entering the latch-up mode.

As shown In FIG. 2, the body of the IGBT device is not directly connected to the emitter of the IGBT device. In addition, the second NMOS transistor Q4 is connected between the emitter of the IGBT device and ground. Such a configuration helps to prevent the latch-up from occurring. More particularly, the base and emitter of the bipolar NPN transistor Q2 form a semiconductor device behaving like a diode. The base is an anode of this diode. The emitter is the cathode of this diode. In operation, the collector current is split into two current components as indicated by dashed lines 201 and 202 respectively. The current flowing through the second NMOS transistor Q4 increases the emitter voltage of the bipolar NPN transistor Q2. In other words, the cathode of the diode has an increased voltage. The increased voltage on the cathode makes the diode become reverse biased. The reverse biased voltage suppresses the turn-on of the diode, thereby preventing the parasitic NPN transistor from being inadvertently turned on.

It should be noted that the method described above comprises a negative feedback mechanism. More particularly, when a large current flowing through the IGBT device, the voltage applied to the base of the NPN transistor increases accordingly. Such an increased base voltage may turn on the parasitic NPN transistor. However, at the same time, the large current flowing through the IGBT device may increase the current flowing through the second NMOS Q4. In response to the increased current flowing through the second NMOS Q4, the drain voltage of the second NMOS Q4 increases too. The increased drain voltage prevents the parasitic NPN transistor from being inadvertently turned on. The increased drain voltage of the second NMOS Q4 forms a negative feedback mechanism.

It should further be noted that the current flowing through the second NMOS Q4 can be adjusted through adjusting a channel width ratio of the MOSFET device (e.g., the second NMOS Q4) to the lateral IGBT device. In particular, by adjusting the channel width ratio, a larger current may flow through the second NMOS Q4. Such a larger current may further increase the drain voltage of the second NMOS Q4, thereby effectively suppressing the turn-on of the parasitic NPN transistor.

FIG. 3 illustrates a simplified top view of a first implementation of the layout of the latch-up free IGBT device shown in FIG. 1 in accordance with various embodiments of the present disclosure. A first collector 301, a gate 303 and a second collector 302 are formed over a drift layer 304. Referring back to FIG. 1, the latch-up free IGBT device 100 further comprises a plurality of p+ and n+ regions such as a body contact (B), a source region (S), a drain region (D) and an emitter region (E). Referring back to FIG. 1, the emitter region is electrically connected to the drain region. In the top view, the emitter region and the drain region are merged in one single region. E/D is used to represent this single region (e.g., E/D regions 311, 312 and 313 in FIG. 3). Referring back to FIG. 1, the body contact is electrically connected to the source region. In the top view, the body contact and the source region are merged in one single region. S/B is used to represent this single region (e.g., S/B regions 321 and 322 in FIG. 3). As shown in FIG. 3, the latch-up free IGBT device comprises a plurality of E/D regions and a plurality of S/B regions. The plurality of E/D regions and the plurality of S/B regions are arranged in an alternating manner.

As shown in FIG. 3, the latch-up free IGBT device comprises an upper portion including three IGBT cells and a lower portion including three IGBT cells. The upper portion of the latch-up free IGBT device is formed by the first collector 301 and the E/D regions 311, 312 and 313. The lower portion of the latch-up free IGBT device is formed by the second collector 302 and the E/D regions 311, 312 and 313. The upper portion and the lower portion are placed in a symmetric manner. For simplicity, only the upper portion will be described below in detail.

A first IGBT cell of the upper portion is formed by the first collector 301 and a first E/D region 311. The gate of the first IGBT cell is oriented from the first collector 301 to the first E/D region 311. An NMOS transistor is formed by the first E/D region 311 and its adjacent S/B region 321 as indicated by the transistor symbol across these two regions. The gate of this NMOS transistor is oriented from the first E/D region 311 to its adjacent S/B region. The gate of the NMOS transistor may be alternatively referred to as a first poly finger. As shown in FIG. 3, the gate of the NMOS transistor is orthogonal to the gate of the first IGBT cell. Referring back to FIG. 2, the NMOS transistor formed by the first E/D region 311 and its adjacent S/B region 321 is part of the second NMOS transistor Q4. The first IGBT cell is part of the IGBT device.

A second IGBT cell of the upper portion is formed by the first collector 301 and a second E/D region 312. The gate of the second IGBT cell is oriented from the first collector 301 to the second E/D region 312. Two NMOS transistors are formed by the second E/D region 312 and its adjacent S/B regions 321 and 322 as indicated by the transistor symbols coupled to the second E/D region 312. The gates of these two NMOS transistors are oriented from the second E/D region 312 to its adjacent S/B regions. The gates of these two NMOS transistors may be alternatively referred to as a second poly finger and a third poly finger, respectively. In sum, the gates of these two NMOS transistors are orthogonal to the gate of the second IGBT cell.

A third IGBT cell of the upper portion is formed by the first collector 301 and a third E/D region 313. The gate of the third IGBT cell is oriented from the first collector 301 to the third E/D region 313. An NMOS transistor is formed by the third E/D region 313 and its adjacent S/B region 322 as indicated by the transistor symbol across these two regions. The gate of this NMOS transistor is oriented from the third E/D region 313 to its adjacent S/B region. The gate of this NMOS transistor may be alternatively referred to as a fourth poly finger. In sum, the gate of this NMOS transistor is orthogonal to the gate of the third IGBT cell.

FIG. 4 illustrates a simplified top view of a second implementation of the layout of the latch-up free IGBT device shown in FIG. 1 in accordance with various embodiments of the present disclosure. The layout of the latch-up free IGBT device shown in FIG. 4 is similar to that shown in FIG. 3 except that the gate of the NMOS transistor is in parallel with the gate the corresponding IGBT cell.

The latch-up free IGBT device comprises an upper portion including one IGBT cell and a lower portion including one IGBT cell. The upper portion of the IGBT device is formed by the first collector 301 and the E/D region 411. The E/D region 411 and the source regions 421, 422, 423 and 424 form four NMOS transistors. The lower portion of the IGBT device is formed by the second collector 302 and the E/D region 412. The upper portion and the lower portion are placed in a symmetric manner. The E/D region 412 and the source regions 421, 422, 423 and 424 form four NMOS transistors. The upper portion and the lower portion are placed in a symmetric manner. For simplicity, only the upper portion will be described below in detail.

A first NMOS transistor of the upper portion is formed by the E/D region 411 and a first source region 421 as indicated by the transistor symbol across these two regions. The gate of the first NMOS transistor is oriented from the E/D region 411 to the first source region 421.The gate of the first NMOS transistor is parallel with the gate of the first IGBT cell.

A second NMOS transistor of the upper portion is formed by the E/D region 411 and a second source region 422 as indicated by the transistor symbol across these two regions. The gate of the second NMOS transistor is oriented from the E/D region 411 to the second source region 422.The gate of the second NMOS transistor is parallel with the gate of the first IGBT cell.

A third NMOS transistor of the upper portion is formed by the E/D region 411 and a third source region 423 as indicated by the transistor symbol across these two regions. The gate of the third NMOS transistor is oriented from the E/D region 411 to the third source region 423.The gate of the third NMOS transistor is parallel with the gate of the first IGBT cell.

A fourth NMOS transistor of the upper portion is formed by the E/D region 411 and a fourth source region 424 as indicated by the transistor symbol across these two regions. The gate of the fourth NMOS transistor is oriented from the E/D region 411 to the fourth source region 424. The gate of the fourth NMOS transistor is parallel with the gate of the first IGBT cell.

It should be noted that the NMOS transistors above collectively form the second NMOS transistor Q4 shown in FIG. 2. The IGBT cells collectively form the IGBT shown in FIG. 2.

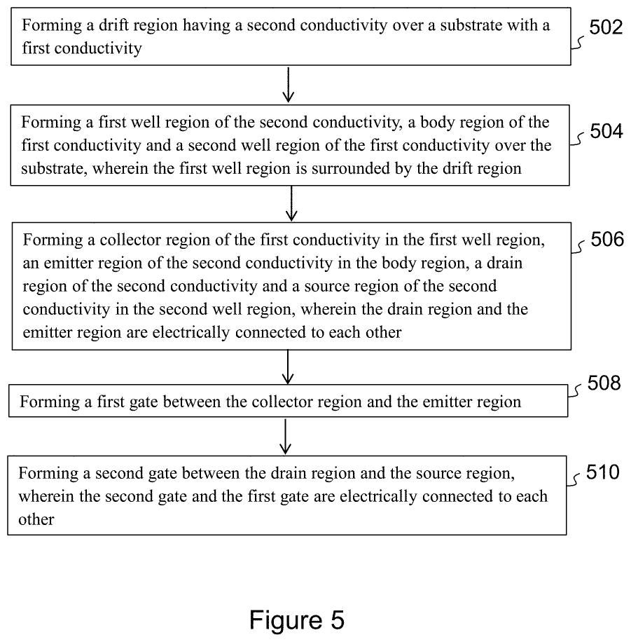

FIG. 5 illustrates a flow chart of a method for forming the latch-up free IGBT device shown in FIG. 1 in accordance with various embodiments of the present disclosure. This flowchart shown in FIG. 5 is merely an example, which should not unduly limit the scope of the claims. One of ordinary skill in the art would recognize many variations, alternatives, and modifications. For example, various steps illustrated in FIG. 5 may be added, removed, replaced, rearranged and repeated.

A latch-up free IGBT device comprises a substrate of a first conductivity, a drift region of a second conductivity formed over the substrate, a body region of the first conductivity formed over the drift region, a first well region of the second conductivity formed over the drift region, a collector region of the first conductivity formed in the well region, an emitter region of the second conductivity formed in the body region, a first body contact of the first conductivity formed in the body region, a first gate situated between the collector region and the emitter region, a second well region of the first conductivity formed over the drift region, a drain region of the second conductivity formed in the second well region, wherein the drain region and the emitter region are electrically connected to each other, a source region of the second conductivity formed in the second well region, wherein the source region and the first body contact are electrically connected to each other, and a second gate situated between the drain region and the source region, wherein the second gate and the first gate are electrically connected to each other.

In some embodiments, the collector region, the emitter region and the first gate form a lateral IGBT device. The drain region, the source region and the second gate form a MOSFET device. In some embodiments, a channel width ratio of the MOSFET device to the lateral IGBT device is selected to prevent the lateral IGBT device from entering a latch-up operating condition.

The latch-up free IGBT device further comprising a second body contact of the first conductivity formed in the second well region. The second body contact and the source region are electrically connected to each other. The latch-up free IGBT device further comprising an STI region extending into the drift region. The first gate is partially over the STI region.

At step 502, a drift region (e.g., region 106 shown in FIG. 1) having a second conductivity over a substrate (e.g., region 102 shown in FIG. 1) with a first conductivity. In some embodiments, the first conductivity is p-type, and the second conductivity is n-type.

At step 504, a first well region (e.g., region 111 shown in FIG. 1) of the second conductivity, a body region (e.g., region 113 shown in FIG. 1) of the first conductivity and a second well region (e.g., region 112 shown in FIG. 1) of the first conductivity over the substrate. The first well region is surrounded by the drift region.

At step 506, a collector region (e.g., region 116 shown in FIG. 1) of the first conductivity is formed in the first well region. An emitter region (e.g., region 114 shown in FIG. 1) of the second conductivity is formed in the body region. A drain region (e.g., drain region 156 shown in FIG. 1) of the second conductivity and a source region (e.g., source region 154 shown in FIG. 1) of the second conductivity are formed in the second well region. The drain region and the emitter region are electrically connected to each other.

At step 508, a first gate (e.g., first gate 124 shown in FIG. 1) is formed between the collector region and the emitter region. At step 510, a second gate (e.g., second gate 162 shown in FIG. 1) is formed between the drain region and the source region. The second gate and the first gate are electrically connected to each other.

The method further comprises growing an epitaxial layer on the substrate and forming a buried layer over the epitaxial layer.

The method further comprises forming the first gate oriented to a first direction and forming the second gate oriented to a second direction. The first gate is a gate of a lateral IGBT device. The second gate is a gate of a MOSFET device. The first direction of the lateral IGBT device is orthogonal to the second direction of the MOSFET device.

The method further comprises forming the first gate oriented to a first direction and forming the second gate oriented to a second direction. The first gate is a gate of a lateral IGBT device. The second gate is a gate of a MOSFET device. The first direction of the lateral IGBT device is parallel with the second direction of the MOSFET device.

The method further comprises forming a first body contact of the first conductivity in the body region and forming a second body contact of the first conductivity in the second well region. The source region and the first body contact are electrically connected to each other. The second body contact and the source region are electrically connected to each other.

Although embodiments of the present disclosure and its advantages have been described in detail, it should be understood that various changes, substitutions and alterations can be made herein without departing from the spirit and scope of the disclosure as defined by the appended claims.

Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. An apparatus comprising:
a substrate of a first conductivity;
a drift region of a second conductivity formed over the substrate;
a body region of the first conductivity formed over the substrate;
a first well region of the second conductivity formed over the drift region;
a collector region of the first conductivity formed in the first well region;
an emitter region of the second conductivity formed in the body region;
a first body contact of the first conductivity formed in the body region;
a first gate situated between the collector region and the emitter region;
a second well region of the first conductivity formed over the substrate;
a drain region of the second conductivity formed in the second well region, wherein the drain region and the emitter region are electrically connected to each other;
a source region of the second conductivity formed in the second well region, wherein the source region and the first body contact are electrically connected to each other; and
a second gate situated between the drain region and the source region, wherein the second gate and the first gate are electrically connected to each other.

2. The apparatus of claim 1, further comprising:
a second body contact of the first conductivity formed in the second well region, wherein the second body contact and the source region are electrically connected to each other.

3. The apparatus of claim 1, further comprising:
a shallow trench isolation (STI) region extending into the drift region.

4. The apparatus of claim 3, wherein:
the first gate is partially over the STI region.

5. The apparatus of claim 1, wherein:
the first conductivity is p-type; and
the second conductivity is n-type.

6. The apparatus of claim 1, wherein:
the first gate is oriented to a first direction; and
the second gate is oriented to a second direction orthogonal to the first direction.

7. The apparatus of claim 1, wherein:
the first gate is oriented to a first direction; and
the second gate is oriented to a second direction in parallel with the first direction.

8. The apparatus of claim 1, wherein:
the collector region, the emitter region and the first gate form a lateral IGBT device; and
the drain region, the source region and the second gate form a MOSFET device, and wherein a channel width ratio of the MOSFET device to the lateral IGBT device is selected to prevent the lateral IGBT device from entering a latch-up operating condition.

9. A method comprising:
forming a drift region having a second conductivity over a substrate with a first conductivity;
forming a first well region of the second conductivity, a body region of the first conductivity and a second well region of the first conductivity over the substrate, wherein the first well region is surrounded by the drift region;
forming a collector region of the first conductivity in the first well region, an emitter region of the second conductivity in the body region, a drain region of the second conductivity and a source region of the second conductivity in the second well region, wherein the drain region and the emitter region are electrically connected to each other;
forming a first gate between the collector region and the emitter region; and
forming a second gate between the drain region and the source region, wherein the second gate and the first gate are electrically connected to each other.

10. The method of claim 9, further comprising:
growing an epitaxial layer on the substrate; and
forming a buried layer over the epitaxial layer, wherein the epitaxial layer and the buried layer are between the substrate and the drift region.

11. The method of claim 9, further comprising:
forming the first gate oriented to a first direction, wherein the first gate is a gate of a lateral IGBT device; and
forming the second gate oriented to a second direction, wherein the second gate is a gate of a MOSFET device, and wherein the first direction is orthogonal to the second direction.

12. The method of claim 9, further comprising:
forming the first gate oriented to a first direction, wherein the first gate is a gate of a lateral IGBT device; and
forming the second gate oriented to a second direction, wherein the second gate is a gate of a MOSFET device, and wherein the first direction is in parallel with the second direction.

13. The method of claim 9, further comprising:
the first conductivity is p-type; and
the second conductivity is n-type.

14. The method of claim 9, further comprising:
forming a first body contact of the first conductivity in the body region, wherein the source region and the first body contact are electrically connected to each other; and
forming a second body contact of the first conductivity in the second well region, wherein the second body contact and the source region are electrically connected to each other.

15. A device comprising:
a first collector region, a gate region and a second collector region formed over a drift layer, wherein the gate region is oriented from the first collector region to the second collector region; and
a plurality of emitter/drain regions and a plurality of source/body regions formed in an alternating manner over the drift layer, wherein:
the first collector region and an emitter region of the plurality of emitter/drain regions form an upper IGBT cell;
the second collector region and the emitter region of the plurality of emitter/drain regions form a lower IGBT cell; and
a drain region of the plurality of emitter/drain regions and a source region of the plurality of source/body regions form an NMOS transistor, and wherein the drain region and the emitter region are electrically connected to each other.

16. The device of claim 15, wherein:
a gate of the NMOS transistor is oriented to a direction orthogonal to a direction of the gate region.

17. The device of claim 16, wherein:
the gate of the NMOS transistor is electrically connected to the gate region.

18. The device of claim 15, wherein:
a gate of the NMOS transistor is oriented to a direction in parallel with a direction of the gate region.

19. The device of claim 18, wherein:
the gate of the NMOS transistor is electrically connected to the gate region.

20. The device of claim 15, further comprising:
a first body contact formed adjacent to the source region; and
a second body contact electrically connected to the source region.
